(19) United States
(12) Patent Application Publication
(10) Pub. No.: US 2026/0223720 A1
(43) Pub. Date: Jul. 30, 2026

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventors: Pierangelo MAGNI, Villasanta (IT); Guendalina CATALANO, Milano (IT)

(73) Assignee: STMicroelectronics International N.V., Geneva (CH)

(21) Appl. No.: 19/462,221

(22) Filed: Jan. 28, 2026

(30) Foreign Application Priority Data
Jan. 29, 2025 (IT) 102025000001593

(51) Int. Cl. H10W 74/01; H10W 72/00; H10W 74/10; H10W 90/00

(52) U.S. Cl. CPC H10W 74/01; H10W 72/016; H10W 74/111; H10W 90/767

(57) ABSTRACT

A semiconductor die is mounted to a die pad of a leadframe including electrically conductive leads. At least one electrically conductive lead has a base lead portion co-planar with the die-pad and a raised lead portion. The leadframe and semiconductor die are encapsulated in an encapsulation of laser direct structuring (LDS) material. At least one electrically conductive path is formed via LDS processing of the encapsulation of LDS material. The at least one electrically conductive path electrically couples the semiconductor die and the at least one electrically conductive lead. The at least one electrically conductive path includes a first electrically conductive via towards the semiconductor die and a second electrically conductive via towards the raised lead portion of the at least one electrically conductive lead.

### PRIORITY CLAIM

This application claims the priority benefit of Italian Application for Patent No. 102025000001593 filed on January 29, 2025, the content of which is hereby incorporated by reference in its entirety to the maximum extent allowable by law.

### TECHNICAL FIELD

The description relates to manufacturing of semiconductor devices.

Solutions as described herein can be applied to Quad Flat No-Leads (QFN) packages for integrated circuit (IC) semiconductor devices for automotive or industrial application, for instance.

### BACKGROUND

In packages for semiconductor devices such as Quad Flat No-leads (QFN) packages, electrical interconnections may be provided via laser direct structuring (LDS).

The LDS technique is based on laser ablation of a molding compound having additive particles embedded therein that are activated when laser energy is applied thereto. Activated particles in the LDS molding compound act as a seed layer, facilitating subsequent plating steps that form electrically conductive interconnections (such as vias and connection lines) as desired.

Interconnections of a device may comprise relatively deep vias formed in the LDS molding compound (to provide electrical coupling to leads of a leadframe, for instance), which may give rise to design and plating issues.

In fact, laser machining cannot drill “vertically” through a molding compound and through-mold-vias (TMVs) are rather formed with a conical (more specifically, frusto-conical) shape (in cross-section). To adequately plate such conical TMVs, the diameter of the vias at the base of the conical shape should be approximately equal to the depth of the vias (thus presenting a 1:1 aspect ratio).

For deep interconnects such a design rule may pose constraints in so far as vias having relatively large base areas that may not fit in package dimensions.

Moreover, several vias in a semiconductor device may be formed in a same plating step (via exposure to a same plating bath for an equal processing time, for instance) and finding suitable parameters of the plating step for plating both “shallow” and “deep” vias may lead to a relatively complex plating step.

There is a need in the art for solutions which aim at addressing the issues discussed in the foregoing.

### SUMMARY

One or more embodiments relate to a method.

One or more embodiments relate to a corresponding (integrated circuit) semiconductor device.

In solutions as described herein, a laser direct structuring (LDS) technique is used to provide electrical coupling between a semiconductor die arranged on a die pad in a leadframe and the leads arranged around the die pad.

In solutions as described herein, one or more leads in the leadframe have a portion raised with respect to the die pad.

In solutions as described herein, electrical coupling between the semiconductor die and the one or more leads having a raised portion is provided by an electrically conductive path comprising a via to the die and a via to the raised portion of the one or more leads.

In solutions as described herein, the via to the semiconductor die and the via to the raised portion of the lead may have substantially equal depths.

In solutions as described herein, one or more leads may have a raised potion and a base portion, with the base portion exposed at a bottom surface of a protective encapsulation of the device.

### BRIEF DESCRIPTION OF THE DRAWINGS

One or more embodiments will now be described, by way of example only, with reference to the annexed figures, wherein:

FIG. 1 is a cross-sectional view illustrative of a structure for a semiconductor device, and

FIGS. 2A to 2G are cross-sectional views illustrative of a sequence of steps for making a device.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

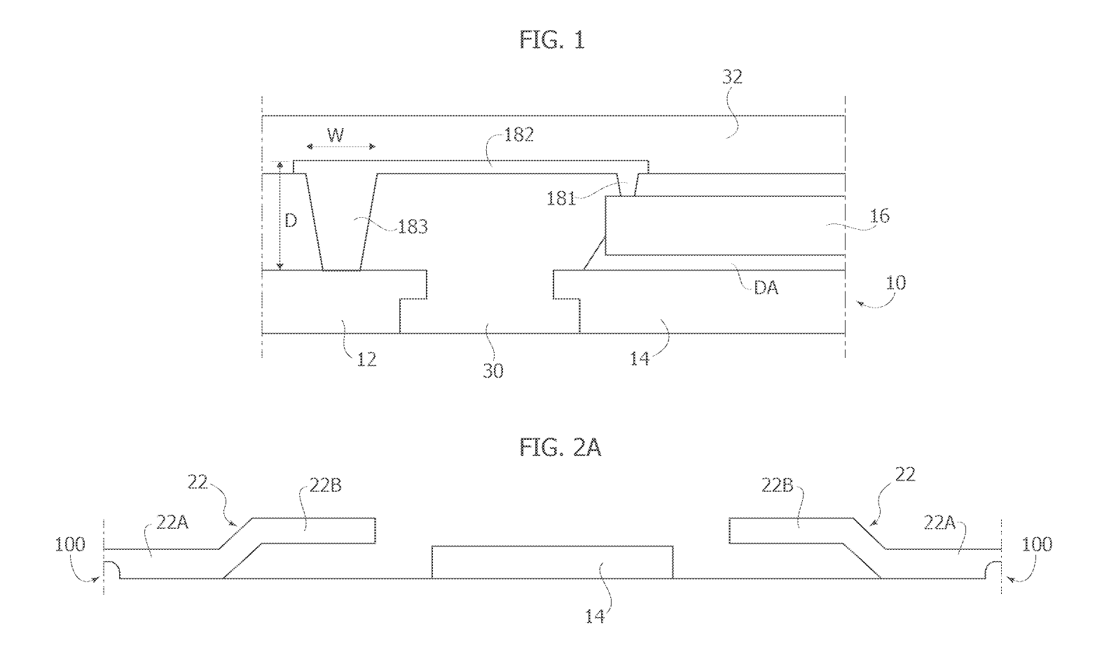

FIG. 1 is illustrative of a structure for a semiconductor device having interconnects formed via laser direct structuring (LDS).

Laser direct structuring (LDS) is a laser-based machining technique now widely used in various sectors of the industrial and consumer electronics markets, for instance for high- performance antenna integration, where an antenna design can be directly formed onto a molded plastic part.

In an exemplary process, the molded parts can be produced with commercially available insulating resins that include additives suitable for the LDS process; a broad range of resins such as polymer resins like PC, PC/ABS, ABS, LCP are currently available for that purpose.

In LDS, a laser beam can be used to transfer (“structure”) a desired electrically-conductive pattern onto a plastic molding that may then be subjected to metallization to finalize a desired conductive pattern.

Metallization (with copper, for instance) may involve electroless plating followed by electrolytic plating.

Electroless plating, also known as chemical plating, is a class of industrial chemical processes that creates metal coatings on various materials by autocatalytic chemical reduction of metal cations in a liquid bath.

In electrolytic plating, an electric field between an anode and a workpiece, acting as a cathode, forces positively charged metal ions to move to the cathode where they give up their charge and deposit as metal on the surface of the work piece.

Reference is made to United States Patent Publication Nos. 2018/0342453 A1, 2019/0115287 A1, 2020/0203264 A1, 2020/0321274 A1, 2021/0050226 A1, 2021/0050299 A1, 2021/0183748 A1, and 2021/0305203 A1 (all incorporated herein by reference) as exemplary of the possibility of applying LDS technology in manufacturing semiconductor devices.

With reference to FIG. 1, a semiconductor device may comprise a semiconductor (Si, SiC or GaN, for instance) die or chip 16 (as used herein the terms die/dice and chip/chips are regarded as synonymous) having an integrated circuit (IC) embedded therein (in any way known in the art), mounted at a die mounting location 14 of a substrate 10, such as a leadframe.

The designation “leadframe” (or “lead frame”) is currently used (see, for instance the USPC Consolidated Glossary of the United States Patent and Trademark Office) to indicate a metal frame that provides support for an integrated circuit die 16 as well as electrical leads 12 to interconnect the integrated circuit in the die to other electrical components or contacts.

Essentially, a leadframe comprises an array of electrically-conductive formations (or leads) 12 that from an outline location extend inwardly in the direction of a semiconductor die 16 thus forming an array of electrically-conductive formations from a die pad 14 configured to have at least one semiconductor die attached thereon, possibly via die-attach material DA provided at the surface of the die pad 14.

As illustrated in FIG. 1, the device may also comprise: an electrically insulating encapsulation 30, 32 providing a protective plastic package to the device, and electrically conductive formations 181, 182, 183 electrically coupling the die 16 to selected leads 12 in the array of electrically conductive leads 12.

Electrically conductive formations 181, 182, 183 as illustrated in FIG. 1 may be provided via an LDS technique as described in the foregoing.

In the case exemplified in FIG. 1 such a process may involve: molding an LDS molding material/compound 30 (for instance, an epoxy resin having LDS additive particles embedded therein) on the leadframe 10 having a semiconductor die 16 mounted thereon; laser structuring the LDS molding compound 30, that is, transferring a desired pattern to the LDS molding compound 30 via laser ablation, thus activating the LDS molding compound at vias 181, 183 and traces 182; growing electrically conductive material (a metallic material such as copper, for instance) to form electrically conductive vias 181, 183 and traces 182 electrically coupling the semiconductor die 16 to the leads 12; and molding an electrically insulating molding compound 32 (for instance, a standard, non-LDS, epoxy resin) to complete the protective plastic package of the device.

As discussed previously, growing electrically conductive material to form vias 181, 183 and traces 182 may involve: growing a “seed” layer of electrically conductive material via electroless deposition, facilitated by the LDS particles activated (by laser beam energy applied thereto) at the surface of the LDS molding compound 30; and growing proper electrically conductive formations 181, 182, 183 onto said seed layer via electrolytic (or galvanic) deposition.

Providing interconnects as illustrated in FIG. 1 formed via LDS technique is per se conventional in the art with such interconnects oftentimes referred to as direct copper interconnects (DCI), due to the extensive – but still, not mandatory – use of copper to form such interconnects with no use of (electrically conductive) wires that can undesirably reduce electrical performance of the device and make the assembly flow more complex (involving, for instance, a wire-bonding formation step).

Conventional LDS techniques as described in the foregoing may suffer from limitations when relatively deep vias are formed.

For instance, laser ablation cannot drill “vertically” through the molding compound, and through-mold-vias (TMVs) are formed with a conical (or frusto-conical) shape; in order to adequately plate such a conical TMV the diameter of the via at the base of the cone should be approximately equal to the depth of the via (that is, a 1:1 aspect ratio).

With reference to FIG. 1, electrically conductive vias 183 to the leads 12 may be relatively deep (via depth is indicated with the reference D in FIG. 1). As mentioned, an aperture having a width W approximately equal to the via depth D is formed at the top surface of the LDS molding compound 30.

A relatively large/wide aperture and, consequently, a relatively large base of the vias 183 may pose constraints on the size and dimensions of the final device. Moreover, laser ablating the LDS molding compound 30 to form such a vias 183 may involve a relatively long lasering time.

Furthermore, vias 181 to the semiconductor die 16 and vias 183 to the leads 12 may have a fairly different depth. As already mentioned, plating vias having such different depths in a same plating bath may result in a relatively complex plating step, where parameters of the plating bath suitable for “shallow” vias (such as the vias 181 to the semiconductor die 16) may be inadequate for “deep” vias (such as the vias 183 to the leads 12) and vice versa.

In solutions as described herein, laser direct structuring (LDS) technique is used to provide electrical coupling between a semiconductor die arranged on a die pad in a leadframe and the leads arranged around the die pad.

In solutions as described herein one or more leads in the leadframe have a portion raised with respect to the die pad.

In solutions as described herein, electrical coupling between the semiconductor die and the one or more leads having a raised portion is provided by an electrically conductive path comprising a via to the die and a via to the raised portion of the one or more leads.

In solutions as described herein, the via to the semiconductor die and the via to the raised portion of the lead may have a depth substantially equal.

In solutions as described herein, one or more leads may have a raised potion and a base portion, with the base portion exposed at a bottom surface of a protective encapsulation of the device.

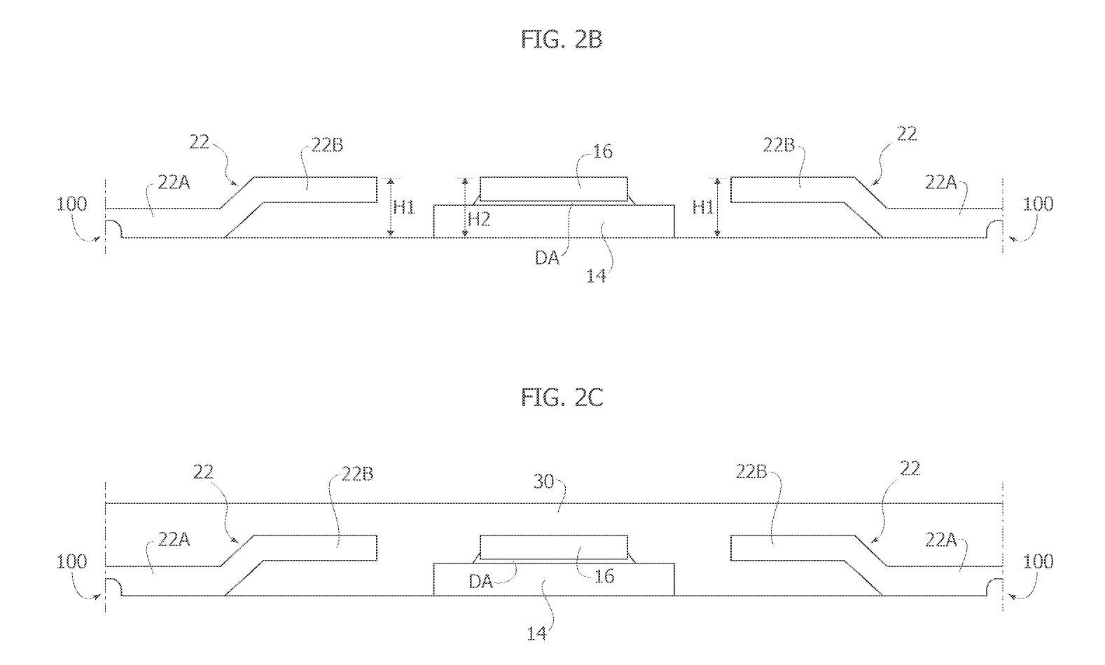

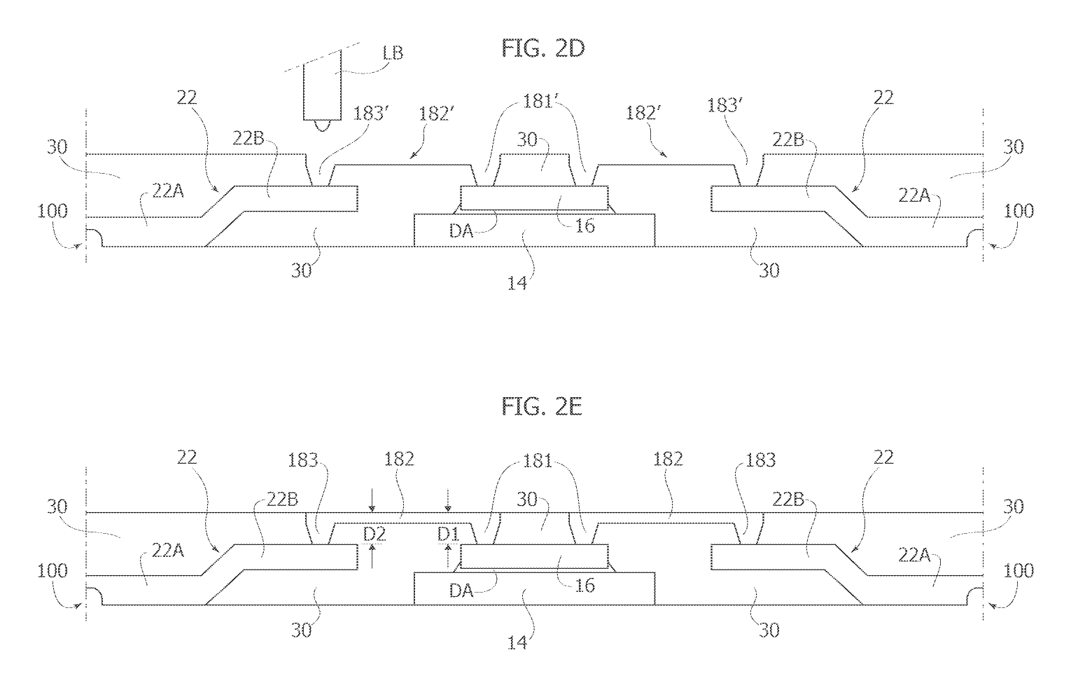

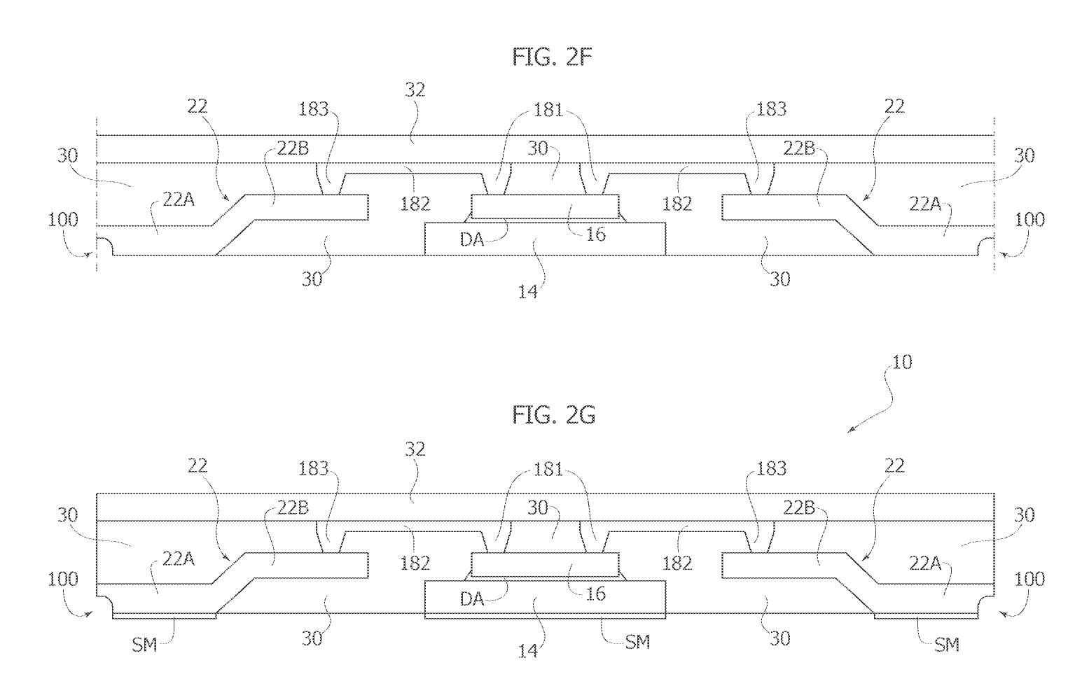

FIGS. 2A to 2G are cross-sectional views illustrative of a sequence of processing steps according to embodiments of the present description.

It will be otherwise appreciated that the sequence of steps of FIGS. 2A to 2G is merely exemplary insofar as: one or more steps illustrated in FIGS. 2A to 2G can be omitted, performed in a different manner (with other tools, for instance) and/or replaced by other steps; additional steps may be added; and one or more steps can be carried out in a sequence different from the sequence illustrated.

FIG. 2A is illustrative of a leadframe 100 according to embodiments of the present description arranged on a temporary (and possibly sacrificial) carrier (not visible in the figures for simplicity).

As illustrated, the leadframe 100 comprises (at least) one die pad 14 configured to have a semiconductor die (such as the semiconductor die 16 illustrated in FIG. 1, for instance) mounted thereon, and an array of electrically conductive leads 22 arranged sidewise of the die pad 14.

In one or more embodiments, the electrically conductive leads 22 have an “S”-like shape, with a base portion 22A at the same level of the die pad 14 and a raised portion 22B, raised with respect to the base portion 22A of the leads 22 (or the die pad 14).

Said otherwise, one or more leads 22 in the array of electrically conductive leads 22 comprise a base lead portion 22A and a raised lead portion 22B, wherein the base lead portion 22A and the die pad 14 comprise leadframe material (copper, for instance) in a first plane (that is, the base lead portion 22A is co-planar with the die-pad 14) and the raised lead portion 22B of the leads 22 comprises leadframe material in a second plane parallel to the first plane (or, equivalently, the die pad 14 is arranged at a downset location with respect to the raised lead portion 22B).

As illustrated in FIG. 2A, the leads 22 may be arranged with the raised lead portion 22B facing the die pad 14.

It is noted that in current manufacturing processes of semiconductor devices, plural devices are manufactured concurrently to be separated into single individual devices in a final singulation. To that effect, a substrate common for a plurality of devices is used (a common substrate such as a leadframe reel or panel, for instance), that comprises a plurality of individual leadframes 100 configured to have mounted thereon at least one semiconductor die. The individual leadframes 100 are connected to form the common substrate via sacrificial connecting bars running between adjacent individual substrates 100, that are removed during the singulation step.

For simplicity and ease of explanation, the following description will refer to manufacturing a single device.

A leadframe 100 as illustrated in FIG. 2A may be provided via per se conventional techniques of leadframe manufacturing (stamping and/or etching of a metal sheet, for instance).

FIG. 2B is illustrative of a processing step wherein a semiconductor die 16 is arranged (via a pick-and-place equipment, for instance) at the die pad 14 in the leadframe 100.

As illustrated, die-attach material DA (a die-attach glue or paste, for instance) is provided at the top/front surface of the die pad 14 to facilitate mounting the semiconductor die 16 thereon.

As illustrated in FIG. 2B, the electrically conductive leads 22 may be shaped in such a way to have the top surface of the raised portion 22B thereof at a height H1 that is approximately equal to the total thickness/height H2 of the assembly formed by the semiconductor die 16 mounted on the die pad 14.

FIG. 2C is illustrative of a molding step wherein an encapsulation 30 of LDS material 30 (that is, an LDS molding compound comprising the molding material with laser-activatable additives) is molded onto the semiconductor die 16 mounted on the leadframe 100. As illustrated, the encapsulation of LDS material 30 is formed with a (top) surface opposite the die pad 14.

FIG. 2D is exemplary of (through-mold) vias and traces/lines therebetween being “structured” or “activated” in the LDS material 30 via laser machining (as indicated by LB) at corresponding locations of the top surface of the encapsulation of LDS material 30.

These locations for the vias 181, 183 and the traces 182 (visible in FIG. 2E, for instance) are indicated by the same reference numbers with an accent in order to highlight the fact that the proper, electrically conductive vias 181, 183 and traces 182 will be formed at those locations only after subsequent metal growth as discussed in the following.

As illustrated: first vias 181’ are opened through the LDS material 30 towards the semiconductor die 16; and second vias 183’ are opened through the LDS material 30 towards the raised portion 22B of the leads 22 arranged sidewise of the die pad 14.

FIG. 2E is illustrative of a processing steps where electrically conductive formations, that is, vias 181, 183 and traces 182, are grown at the locations 181’, 182’, 183’ of the encapsulation of LDS material structured previously.

As already discussed, this may involve: growing a “seed” layer of electrically conductive material (copper, for instance) via electroless deposition at the structured locations 181’, 182’, 183’ of the encapsulation of LDS material 30, facilitated by the LDS additive particles activated (by laser beam energy applied thereto) at the surface of the LDS material 30; and growing, via electrolytic/galvanic plating, further electrically conductive material (again copper, for instance) onto said seed layer, to form electrically conductive vias 181, 183 and traces 182.

As illustrated, electrically conductive paths are formed between the semiconductor die 16 (that is, from the die bonding pads at the top/front surface of the semiconductor die 16, not visible in the figures for scale reasons) and selected leads 22 in the array of electrically conductive leads 22. The electrically conductive paths comprise: first vias 181 to the semiconductor die 16; second vias 183 to the electrically conductive leads 22; and traces 182 extending at the top surface of the encapsulation of LDS material 30 between the first 181 and the second 183 vias.

It may be appreciated that a second via 183 to the raised portion 22B of an electrically conductive lead 22 is shorter than (i.e., not as deep as) a via to the base portion 22A of the same lead 22 (see, also, for comparison, lead 1283 of FIG. 1). As discussed previously, a shorter via may be advantageous in so far as the “design rule” of an aspect ratio of 1:1 between the base of the via and the depth of the via poses less limitations on package design and dimensions.

In one or more embodiments, the leads 22 may be formed with a raised portion 22B having a height H1 such that the first vias 181 to the semiconductor die 16 and the second vias 183 to the raised portion 22B of the electrically conductive leads 22 have a depth substantially equal, that is, extend over lengths through the encapsulation of LDS material 30 that are substantially equal.

As discussed previously, vias 181, 183 having a (substantially) equal depth may simplify the plating step to form proper, electrically conductive vias 181, 183.

FIG. 2F is illustrative of a processing step wherein a further (electrically insulating) encapsulation 32 is molded onto the device 10. The further electrically insulating encapsulation 32 may comprise a standard, that is, non-LDS, molding compound (an epoxy resin, for instance).

As illustrated, the further electrically insulating encapsulation 32 encapsulates the electrically conductive paths 181, 182, 183 electrically coupling the semiconductor die 16 to the leads 22.

FIG. 2G is illustrative of a (finished) semiconductor device 10 obtained subsequently to providing solder material SM at the back/bottom surface of the leadframe 100 (the surface that is exposed at the back/bottom surface of the encapsulation of LDS material 30) and subsequently to singulation of the panel/reel into individual devices 10.

As illustrated, the back or bottom surface of the base portion 22A of the leads 22 is exposed at the back/bottom surface of the encapsulation of LDS material 30 and, consequently, solder material SM may be provided also thereon to facilitate mounting the semiconductor device 10 onto a final substrate (a printed circuit board, PCB, for instance).

In summary, solutions as described with reference to the figures comprise arranging a semiconductor die 16 at a die pad 14 of a leadframe 100 comprising an array of electrically conductive leads 22 around the die pad 14.

At least one lead 22 in the array of electrically conductive leads 22 comprises a base lead portion 22A co-planar with the die-pad 14 and a raised lead portion 22B, wherein the die pad 10 is arranged at a downset location with respect to said raised lead portion 22B.

The leadframe 100 and the semiconductor die 16 arranged thereon are encapsulated in an encapsulation of laser direct structuring, LDS, material 30.

At least one electrically conductive path 181, 182, 183 is formed via LDS processing of the encapsulation of LDS material 30 (via the processing steps described with reference to FIGS. 2D and 2E, for instance) to electrically couple the semiconductor die 16 and the at least one lead 22 in the array of electrically conductive leads 22.

The at least one electrically conductive path 181, 182, 183 comprises a first electrically conductive via 181 towards the semiconductor die 16 and a second electrically conductive via 183 towards the raised lead portion 22B of the at least one lead 22 in the array of electrically conductive leads 22.

The first electrically conductive via 181 extends towards the semiconductor die 16 over a first length through the encapsulation of LDS material 30 and the second electrically conductive via 182 extends towards said raised lead portion 22B of the at least one lead 22 in the array of electrically conductive leads 22 over a second length through the encapsulation of LDS material 30, wherein, advantageously, the first length may be substantially equal to the second length.

In one or more embodiments, the at least one lead 22 in the array of electrically conductive leads 22 comprises a raised lead portion 22B arranged proximally of the die pad 14.

Embodiments wherein the raised lead portion 22B is arranged distally of the die pad 14 or, equivalently, with the base lead portion 22A arranged proximally of the die pad 14, are also possible.

In one or more embodiments, first leads 22 may be arranged with the base portion 22A proximally of the die pad 14 and second leads 22 may be arranged with the raised portion 22B proximally of the die pad 14.

Further electrically insulating encapsulation 32 may be molded onto the encapsulation of LDS material 30 having the at least one electrically conductive path 181, 182, 183 formed therein. The further electrically insulating encapsulation 32 encapsulates the at least one electrically conductive path 181, 182, 183.

In one or more embodiments, the encapsulation of LDS material 30 encapsulating the leadframe 100 and the semiconductor die 16 arranged thereon has first and second opposite surfaces. The at least one electrically conductive path 181, 182, 183 in the encapsulation of LDS material 30 is formed via LDS processing of the first surface of the encapsulation of LDS material 30. The die pad 12A and the base lead portion 22A of the at least one lead 22 are exposed at the second surface of the encapsulation of LDS material 30.

Without prejudice to the underlying principles, the details and embodiments may vary, even significantly, with respect to what has been described by way of example only without departing from the extent of protection.

The extent of protection is determined by the annexed claims.

The claims are an integral part of the technical teaching provided in respect of the embodiments.

1. A method, comprising:
arranging a semiconductor die at a die pad of a leadframe comprising an array of electrically conductive leads around the die pad, wherein at least one lead in the array of electrically conductive leads comprises a base lead portion co-planar with the die-pad and a raised lead portion, wherein the die pad is arranged at a downset location with respect to said raised lead portion;
encapsulating the base and raised lead portions of the leadframe and the semiconductor die arranged on the die pad in an encapsulation of laser direct structuring (LDS) material; and
forming, via LDS processing of the encapsulation of LDS material, at least one electrically conductive path electrically coupling the semiconductor die and the at least one lead in the array of electrically conductive leads, wherein said at least one electrically conductive path comprises a first electrically conductive via towards the semiconductor die and a second electrically conductive via towards said raised lead portion of said at least one lead in the array of electrically conductive leads.

2. The method of claim 1, wherein the first electrically conductive via extends towards the semiconductor die over a first length through the encapsulation of LDS material and the second electrically conductive via extends towards said raised lead portion of said at least one lead in the array of electrically conductive leads over a second length through the encapsulation of LDS material, wherein said first length is substantially equal to said second length.

3. The method of claim 1, wherein said raised lead portion is arranged proximally of the die pad.

4. The method of claim 1, comprising molding a further electrically insulating encapsulation onto the encapsulation of LDS material having said at least one electrically conductive path formed therein, wherein said further electrically insulating encapsulation encapsulates said at least one electrically conductive path.

5. The method of claim 1, wherein the encapsulation of LDS material encapsulating the leadframe and the semiconductor die arranged thereon has first and second opposite surfaces, wherein said at least one electrically conductive path in the encapsulation of LDS material is formed via LDS processing of said first surface of the encapsulation of LDS material and wherein the die pad and the base lead portion of said at least one lead are exposed at said second surface of the encapsulation of LDS material.

6. The method of claim 1, wherein a surface of the base lead portion is exposed at a bottom side of the encapsulation.

7. A device, comprising:
a semiconductor die arranged at a die pad of a leadframe comprising an array of electrically conductive leads around the die pad, wherein at least one lead in the array of electrically conductive leads comprises a base lead portion co-planar with the die-pad and a raised lead portion, wherein the die pad is arranged at a downset location with respect to said raised lead portion;
an encapsulation of laser direct structuring (LDS) material encapsulating the base and raised lead portions of the leadframe and the semiconductor die arranged on the die pad; and
at least one electrically conductive path formed via LDS processing of the encapsulation of LDS material, electrically coupling the semiconductor die and the at least one lead in the array of electrically conductive leads, wherein said at least one electrically conductive path comprises a first electrically conductive via towards the semiconductor die and a second electrically conductive via towards said raised lead portion of said at least one lead in the array of electrically conductive leads.

8. The device of claim 7, wherein the first electrically conductive via extends towards the semiconductor die over a first length through the encapsulation of LDS material and the second electrically conductive via extends towards said raised lead portion of said at least one lead in the array of electrically conductive leads over a second length through the encapsulation of LDS material, wherein said first length is substantially equal to said second length.

9. The device of claim 7, wherein said at least one lead in the array of electrically conductive leads comprises a raised lead portion arranged proximally of the die pad.

10. The device of claim 7, comprising a further electrically insulating encapsulation molded onto the encapsulation of LDS material having said at least one electrically conductive path formed therein, wherein said further electrically insulating encapsulation encapsulates said at least one electrically conductive path.

11. The device of claim 7, wherein the encapsulation of LDS material encapsulating the leadframe and the semiconductor die arranged thereon has first and second opposite surfaces, wherein said at least one electrically conductive path in the encapsulation of LDS material is formed via LDS processing of said first surface of the encapsulation of LDS material and wherein the die pad and the base lead portion of said at least one lead are exposed at said second surface of the encapsulation of LDS material.

12. The device of claim 7, wherein a surface of the base lead portion is exposed at a bottom side of the encapsulation.
